(19) United States
(12) Patent Application Publication
(10) Pub. No.: US 2026/0271190 A1
(43) Pub. Date: Sep. 10, 2026

(54) LOW-INDUCTANCE CURRENT-SHARING POWER MODULE

(71) Applicant: YANGZHOU GUOYANG ELECTRONIC CO., LTD., Jiangsu (CN)

(72) Inventors: Jianxiang XIAO, Jiangsu (CN); Fengbin HAO, Jiangsu (CN); Yang YANG, Jiangsu (CN); Jie LIU, Jiangsu (CN)

(73) Assignee: YANGZHOU GUOYANG ELECTRONIC CO., LTD., Jiangsu (CN)

(21) Appl. No.: 18/857,819

(22) PCT Filed: Feb. 20, 2024
(86) PCT No.: PCT/CN2024/077707

§ 371 Date: Oct. 18, 2024

(30) Foreign Application Priority Data
Oct. 9, 2023 (CN) 202311297416.X

(51) Int. Cl. H05K 1/181; H05K 1/03; H05K 1/09; H05K 1/11

(52) U.S. Cl. CPC H05K 1/181; H05K 1/0306; H05K 1/09; H05K 1/11

(57) ABSTRACT

A low-inductance current-sharing power module, including a bottom plate, a first chipset, a second chipset, a positive electrode, a negative electrode and an output electrode is provided. A first substrate, a second substrate and a negative-electrode substrate are installed on the upper surface of the bottom plate. The first chipset and the positive electrode are installed on the upper surface of the first substrate, and the first chipset is in connection with the second substrate through a first link device. The second chipset and the output electrode are installed on the upper surface of the second substrate, and the second chipset is in connection with the negative-electrode substrate through the second link device. The negative electrode is installed on the upper surface of the negative-electrode substrate, and the first link device and the second link device are arranged in a laminated manner.

### TECHNICAL FIELD

The present disclosure relates to the technical field of the power-electronics power module, and specifically but not limited to a low-inductance current-sharing power module.

### DESCRIPTION OF RELATED ART

A schematic diagram of a packaging structure of a traditional power module is as illustrated in FIG. 1, which includes a positive electrode 1-1, a positive electrode 1-2, a negative electrode 2, an output electrode 8 and a substrate. The upper-bridge chips and the positive electrode 1-1 and the positive electrode 1-2 are arranged on the upper-bridge copper-sheet area 3-1, and are in connection with the substrate where the output electrode 8 is located and the substrate where the lower-bridge chips 4-2 are located through the metal wires or the metal strips. The lower-bridge chips 4-2 are arranged on the island substrate and is in connection with the substrate where the output electrode 8 is located through the metal wires or the metal strips. The loop of the main circuit between the positive electrode 1-1, positive electrode 1-2 and the negative electrode 2 of the whole power module is long and the parasitic inductance of the main circuit between the positive electrode 1-1, positive electrode 1-2 and the negative electrode 2 of the whole power module is large, which significantly limits the performance of the power module.

In order to further improve the performance of the module and reduce the parasitic inductance of the module, it is necessary to develop a low-inductance current-sharing power module.

### SUMMARY

In view of one or more problems in the prior art, a low-inductance current-sharing power module is provided in the present disclosure, which varies the existing arrangement of the power module chips, and arranges the upper and lower bridge chips on the upper and lower bridge substrates, then connects the upper and lower bridge chips with the upper and the lower bridge substrates through the upper and lower bridge link devices, and places the upper and lower bridge link devices in a laminated manner, so that the parasitic inductance of the power loop is significantly reduced by making full use of the effect of the magnetic field cancellation, thereby effectively reducing the loss of the power module and improving the usage frequency of the power module.

The technical solutions to achieve the objectives of the present disclosure are as follows.

Provided is a low-inductance current-sharing power module. The module includes a ceramic substrate, a first chipset, a second chipset, positive electrodes, a negative electrode and an output electrode.

An upper-layer copper sheet is arranged on an upper surface of the ceramic substrate, and the upper-layer of copper sheet includes a first copper-sheet area, a second copper-sheet area, a negative-electrode copper-sheet area and a signal copper-sheet area that are not connected to each other.

The first chipset is evenly arranged on an upper surface of the first copper-sheet area and is coupled to the second copper-sheet area through a first link device.

The second chipset is evenly arranged on an upper surface of the second copper-sheet area and is coupled to the negative-electrode copper-sheet area and the signal copper-sheet area through a second link device, and the second link device and the first link device are arranged in a laminated manner.

The positive electrode is coupled to the first copper-sheet area and extends outward, the negative electrode is coupled to the negative-electrode copper-sheet area and extends outward, and the output electrode is coupled to the second copper-sheet area and extends outward.

Further, in the low-inductance current sharing power module of the present disclosure, the first copper-sheet area is arranged on a right half of the upper surface of the ceramic substrate and is in a “concave” shape, and the second copper-sheet area is arranged on a left half of the upper surface of the ceramic substrate and is in a “convex” shape, the negative-electrode copper-sheet area is arranged at an intermediate part of a right edge of the upper surface of the ceramic substrate and is semi-surrounded within the “concave”-shaped first copper-sheet area, the signal copper-sheet area is arranged at both ends of a left edge of the upper surface of the ceramic substrate and is located at both sides of a top part of the “convex”-shaped second copper-sheet area, and the signal copper-sheet area includes paths respectively extending into the first copper-sheet area and the second copper-sheet area, and the path extending into the first copper-sheet area and the path extending into the second copper-sheet area are in bilateral symmetry with respect to a center line of the upper surface of the ceramic substrate.

Further, in the low-inductance current-sharing power module of the present disclosure, the first chipset arranged on the first copper-sheet area and the second chipset arranged on the second copper-sheet area are in bilateral symmetry with respect to the center line of the ceramic substrate.

Further, in the low-inductance current-sharing power module of the present disclosure, two positive electrodes are respectively arranged on both protruded ends of the “concave”-shaped first copper-sheet area, and the negative electrode is arranged on the negative-electrode copper-sheet area, the two positive electrodes are symmetrical with respect to the negative electrode.

Further, in the low-inductance current-sharing power module of the present disclosure, the first link device and the second link device are respectively coupled to the first chipset and the second chipset through metal blocks.

Further, in the low-inductance current-sharing power module of the present disclosure, the first link device includes a first link body, a first link pin and first metal blocks of a number of p, and the first link body is respectively coupled to p chips of the first chipset through the p first metal blocks, where p denotes a positive integer, the first link body is coupled to the second copper-sheet area through the first link pin.

Further, the low-inductance current-sharing power module of the present disclosure, the second link device includes a second link body, a second link pin, a third link pin and second metal blocks of a number of q, the second link body is respectively coupled to q chips of the second chipset through q second metal blocks, and a thickness of the second metal block is greater than a thickness of the first metal block, where q denotes a positive integer, the second link body is coupled to the negative-electrode copper-sheet area through the second link pin, and the second link body is coupled to the signal copper-sheet area through the third link pin.

Further, in the low-inductance current-sharing power module of the present disclosure, the first link device includes a first link body and a plurality of link pins, and a first end of each of the link pins is in connection with the first link body, a second end of each of p link pins is respectively coupled to p chips of the first chipset, and a second end of each of remaining link pins is coupled to the second copper-sheet area, where p denotes a positive integer.

Further, in the low-inductance current-sharing power module of the present disclosure, the second link device includes a second link body and a plurality of link pins, a first end of each of the link pins is in connection with the second link body, a second end of each of q link pins is respectively coupled to q chips of the second chipset, and a second end of each of r link pins is coupled to the negative-electrode copper-sheet area, and a second end of each of the remaining link pins is coupled to the signal copper-sheet area, where q and r denote positive integers.

Further, the low-inductance current-sharing power module of the present disclosure further includes a G electrode and an S electrode, the G electrode and the S electrode are respectively in connection with the signal copper-sheet areas at different positions and are extended outward, the S electrode is in connection with the second link device through the signal copper-sheet area.

In comparison with the prior art, the above technical solutions adopted by the present disclosure have the following technical effects.

In the present disclosure, the existing arrangement of the chips of the power module is varied, the upper-bridge chips are evenly arranged on the upper-bridge substrate, then the upper-bridge chips are in connection with the lower-bridge substrate through the upper-bridge link device, the lower-bridge chips are evenly arranged on the lower-bridge substrate, then the lower-bridge chips are in connection with the negative-electrode substrate through the lower-bridge link device, and the upper-bridge link device and the lower-bridge device are placed in a laminated manner, so that the parasitic inductance of the power loop is significantly reduced through the effect of the magnetic field cancellation, therefore effectively reducing the loss of the power module and improving the usage frequency of the power module.

### BRIEF DESCRIPTION OF THE DRAWINGS

The accompanying drawings are utilized to provide a further understanding of the present disclosure, and are utilized to illustrate the embodiments of the present disclosure together with the description, but do not constitute a limitation of the present disclosure.

FIG. 1 illustrates a schematic diagram of a packaging structure of a traditional power module.

FIG. 2 illustrates a schematic diagram of an overall packaging structure in an embodiment of a low-inductance current-sharing power module of the present disclosure.

FIG. 3 illustrates an unfolding schematic diagram of an upper-bridge link device in an embodiment of the low-inductance current-sharing power module of the present disclosure.

FIG. 4 illustrates a top view of an embodiment of the low-inductance current-sharing power module without link devices of the present disclosure.

FIG. 5 illustrates a schematic structural diagram of an upper-bridge link device in an embodiment of the low-inductance current-sharing power module of the present disclosure.

FIG. 6 illustrates a schematic structural diagram of a lower-bridge link device in an embodiment of the low-inductance current-sharing power module of the present disclosure.

FIG. 7 illustrates a schematic diagram of an overall packaging structure in another embodiment of the low-inductance current-sharing power module of the present disclosure.

FIG. 8 illustrates an unfolding schematic diagram of an upper-bridge link device in another embodiment of the low-inductance current-sharing power module of the present disclosure.

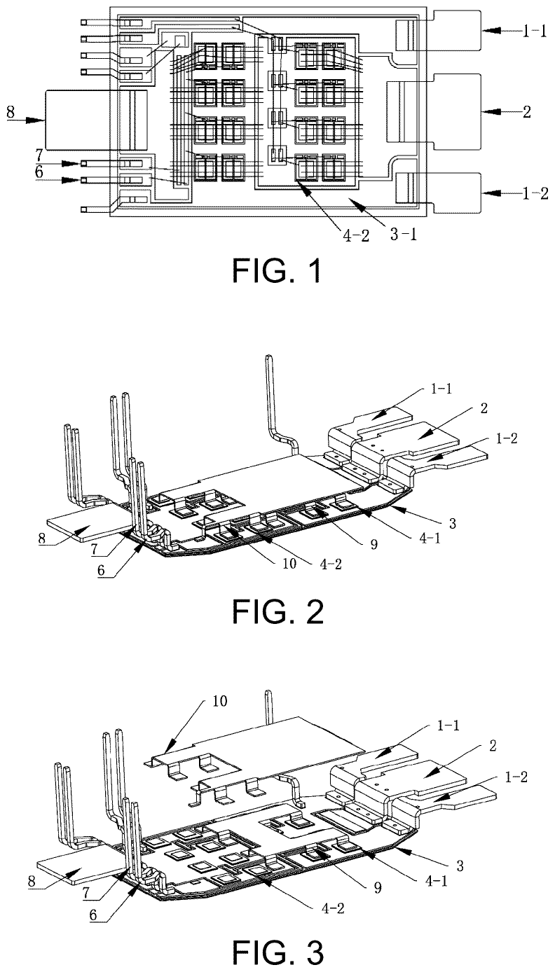

The relevant numerals in the drawings: 1-1. Positive electrode; 1-2. Positive electrode 2. Negative electrode; 3. Ceramic substrate; 3-1. Upper-bridge copper-sheet area; 3-2. Lower-bridge copper-sheet area; 3-3. Negative-electrode copper-sheet area; 4. Chipset; 4-1. Upper-bridge chipset; 4-2. Lower-bridge chipset; 6. G electrode; 7. S electrode; 8. Output electrode; 9. Upper-bridge link device; 9.1 to 9.12. Link pins of the upper-bridge link device, 10. Lower-bridge link device; 10.1 to 10.9. Link pins of the lower-bridge link device; 10.10. S electrode link pins, 11. Metal block; 11.1. Upper-bridge metal block; 11.2. Lower-bridge metal block.

### DESCRIPTION OF THE EMBODIMENTS

In order to further understand the present disclosure, the preferred embodiments of the present disclosure are described below with reference to the embodiments. However, it should be understood that these descriptions are merely to further illustrate the features and advantages of the present disclosure, rather than to limit the claims of the present disclosure.

The descriptions in this part are merely for the typical embodiments, and the present disclosure is not limited to the scope described by the embodiments. The combinations of the different embodiments, the substitutions between some technical features in different embodiments, and the substitutions between the same or similar existing technical means and some technical features in the embodiments are also within the scope of descriptions and protection of the present disclosure.

A low-inductance current-sharing power module includes a ceramic substrate 3, an upper-bridge chipset 4-1, a lower-bridge chipset 4-2, a positive electrode 1-1, a positive electrode 1-2, a negative electrode 2 and an output electrode 8. An upper-layer copper sheet is arranged on the ceramic substrate 3, and the upper-layer copper sheet includes an upper-bridge copper-sheet area 3-1, a lower-bridge copper-sheet area 3-2, a negative-electrode copper-sheet area 3-3 and a signal copper-sheet area that are not connected to each other. The upper-bridge chipset 4-1 is evenly arranged on the upper surface of the upper-bridge copper-sheet area 3-1, and the upper-bridge chipset 4-1 is in connection with the lower-bridge copper-sheet area 3-2 through an upper-bridge link device 9. The lower-bridge chipset 4-2 is evenly arranged on the upper surface of the lower-bridge copper-sheet area 3-2, and the lower-bridge chipset 4-2 is in connection with the negative-electrode copper-sheet area 3-3 and the signal copper-sheet area through a lower-bridge link device 10. The upper-bridge link device 9 and the lower-bridge link device 10 are arranged in a laminated manner. The positive electrodes 1-1 and the positive electrode 1-2 are installed on the upper-bridge copper-sheet area 3-1 and extend outward, the negative electrode 2 is installed on the negative-electrode copper-sheet area 3-3 and extends outward, and the output electrode 8 is installed on the lower-bridge copper-sheet area 3-2 and extends outward.

### Embodiment 1

As illustrated in FIGS. 2 to 4, a low-inductance current-sharing power module includes a ceramic substrate 3, an upper-bridge chipset 4-1, a lower-bridge chipset 4-2, a positive electrode 1-1, a positive electrode 1-2, a negative electrode 2 and an output electrode 8.

An upper-layer cooper sheet is arranged on the upper surface of the ceramic substrate 3, and the upper-layer copper sheet includes an upper-bridge copper-sheet area 3-1, a lower-bridge copper-sheet area 3-2, a negative electrode copper-sheet area 3-3 and a signal copper-sheet area that are not connected to each other.

Specifically, the upper-bridge copper-sheet area 3-1 is arranged on the right half of the upper surface of the ceramic substrate 3 and is in a “concave” shape, and the lower-bridge copper-sheet area 3-2 is arranged on the left half of the upper surface of the ceramic substrate 3 and is in a “convex” shape. The main part of the upper-bridge copper-sheet area 3-1 and the main part of the lower-bridge copper-sheet area 3-2 are approximately in bilateral symmetry with respect to the center line of the upper surface of the ceramic substrate 3. In one specific embodiment, the upper-bridge chipset 4-1 arranged on the upper-bridge copper-sheet area 3-1 and the lower-bridge chipset 4-2 arranged on the lower-bridge copper-sheet area 3-2 are in a bilateral symmetry with respect to the center line of the upper surface of the ceramic substrate.

Specifically, the negative-electrode copper-sheet area 3-3 is arranged at an intermediate part of the right edge of the upper surface of the ceramic substrate 3 and is semi-surrounded within the “concave”-shaped upper-bridge copper-sheet area 3-1. The remaining parts of the negative-electrode copper-sheet area 3-3 are surrounded by the upper-bridge copper-sheet area 3-1 except one edge of the negative-electrode copper-sheet area 3-1. In one specific embodiment, the positive electrode 1-1 and the positive electrode 1-2 are respectively arranged at two protruded ends of the “concave”-shaped upper-bridge copper-sheet area 3-1, whereas the negative electrode 2 is arranged on the negative-electrode copper-sheet area 3-3, so that the positive electrode 1-1 and the positive electrode 1-2 are symmetrical with respect to the negative electrode 2.

Specifically, the signal copper-sheet area is arranged at both ends of the left edge of the upper surface of the ceramic substrate 3 and is located on both sides of the top part of the “convex”-shaped lower-bridge copper-sheet area 3-2, and includes the paths respectively extending into the upper-bridge copper-sheet 3-1 and the lower-bridge copper-sheet area 3-2, specifically, the path extending into the upper-bridge copper-sheet area 3-1 and the path extending into the lower-bridge copper-sheet area 3-2 are in bilateral symmetry with respect to the center line of the upper surface of the ceramic substrate.

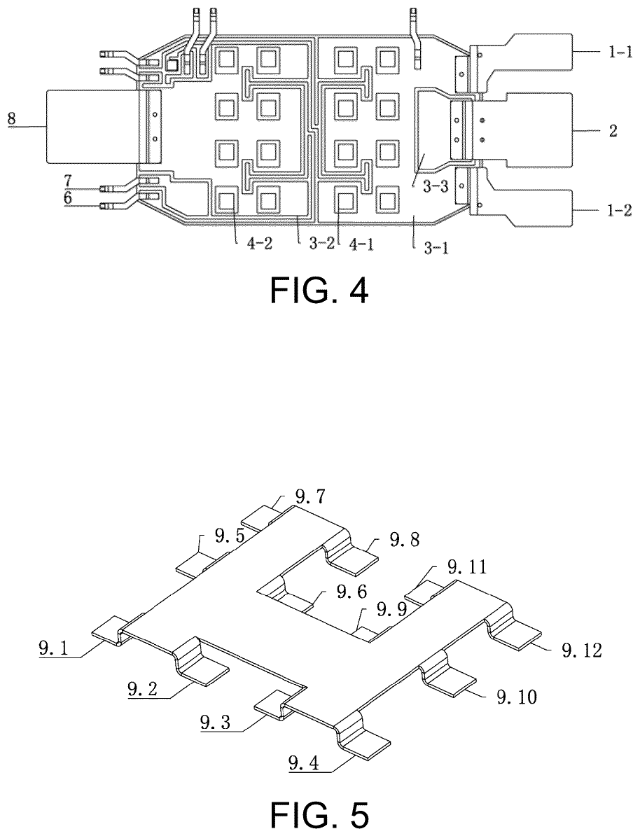

The upper-bridge chipset 4-1, the positive electrode 1-1 and the positive electrode 1-2 are installed on the upper surface of the upper-bridge copper-sheet area 3-1, the upper-bridge chipset 4-1 is evenly arranged on the upper-bridge copper-sheet area 3-1 to achieve the current sharing effect, and the upper-bridge chipset 4-1 is in connection with the lower-bridge copper-sheet area 3-2 through the upper-bridge link device 9. The positive electrode 1-1 and the positive electrode 1-2 are coupled to the two protruded ends of the “concave”-shaped upper-bridge copper-sheet area 3-1 and extend outward to facilitate to connect with the exterior. In one specific embodiment, as illustrated in FIG. 4, the upper-bridge chipset 4-1 includes eight upper-bridge chips, and the eight upper-bridge chips are evenly arranged on the upper surface of the upper-bridge copper-sheet area 3-1 in four rows and two columns. The path of the signal copper-sheet area extending into the upper-bridge copper-sheet area 3-1 is divided into two paths that respectively extend into the centers of the four upper-bridge chips located at the upper part of the upper-bridge chipset 4-1 and the centers of the four upper-bridge chips located at the lower part of the upper-bridge chipset 4-1. In another specific embodiment, as illustrated in FIG. 5, the upper-bridge link device 9 includes an upper-bridge link body and twelve link pins 9.1 to 9.12. One end of each of the twelve link pins 9.1 to 9.12 is in connection with the upper-bridge link body, and the other end of each of the eight link pins 9.5 to 9.12 is respectively coupled to the eight upper-bridge chips of the upper-bridge chipset 4-1, and the other end of each of the remaining four link pins 9.1 to 9.4 is in connection with the lower-bridge copper-sheet area 3-2.

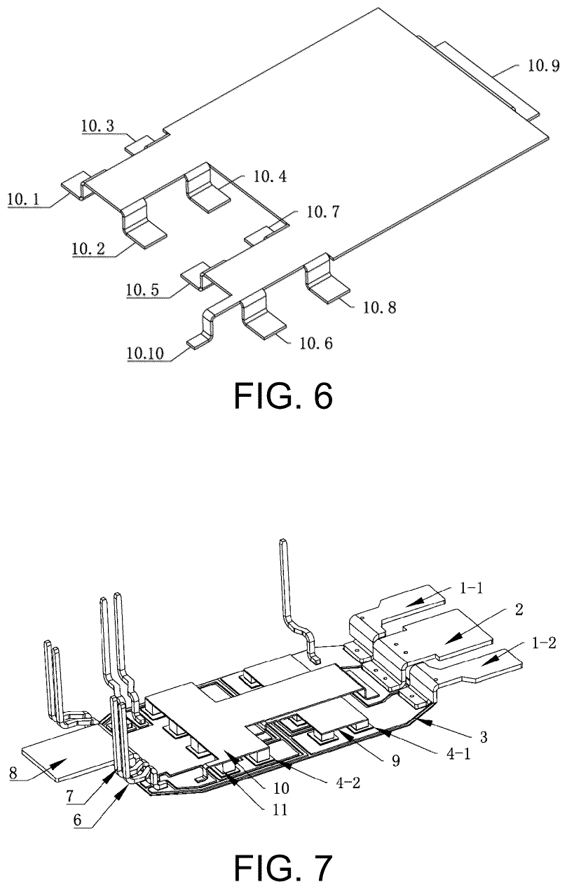

The lower-bridge chipset 4-2 and the output electrode 8 are installed on the upper surface of the lower-bridge copper-sheet area 3-2, the lower bridge chipset 4-2 is evenly arranged on the upper surface of the lower-bridge copper-sheet area 3-2 to achieve the current sharing effect, and the lower-bridge chipset 4-2 is in connection with the negative-electrode copper-sheet area 3-3 through the lower-bridge link device 10. The output electrode 8 is coupled to the lower-bridge copper-sheet area 3-2 and extends outward to facilitate to connect with the exterior. In one specific embodiment, as illustrated in FIG. 4, the lower-bridge chipset 4-2 includes eight lower-bridge chips, and the eight lower-bridge chips are evenly arranged on the upper surface of the lower-bridge copper-sheet area 3-2 in four rows and two columns, the eight lower-bridge chips and the eight upper-bridge chips are in bilateral symmetry with respect to the center line of the upper surface of the ceramic substrate 3, and the path of the signal copper-sheet area extending into the lower-bridge copper-sheet area 3-2 is divided into two paths that respectively extend into the centers of the four lower-bridge chips located at the upper part of the lower-bridge chipset 4-1 and the centers of the four lower-bridge chips located at the lower part of the lower-bridge chipset 4-1. In another specific embodiment, as illustrated in FIG. 6, the lower-bridge link device 10 includes a lower-bridge link body and ten link pins 10.1 to 10.10, one end of each of the ten link pins 10.1 to 10.10 is in connection with the lower-bridge link body, and the other end of each of the eight link pins 10.1 to 10.8 is respectively coupled to the eight low-bridge chips of the low-bridge chipset 4-2, the other end of the link pin 10.9 is coupled to the negative-electrode copper-sheet area 3-3, and the other end of the remaining link pin 10.10 is coupled to the signal copper-sheet area.

The negative electrode 2 is installed on the upper surface of the negative-electrode copper-sheet area 3-3 and extend outward to facilitate to connect with the exterior.

The upper-bridge link device 9 and the lower-bridge link device 10 are arranged in a laminated manner, that is, the upper bridge link device 9 and the lower bridge link device 10 are partially overlapped but are not coincide with each other.

The current loops and the signal current loops of the main circuit of the upper and lower bridges are symmetrical respectively through the symmetrical arrangement of the copper-sheet areas and the chipsets, as well as the laminated arrangement of the link devices, which reduces the loss and improves the current sharing effect effectively.

### Embodiment 2

As illustrated in FIGS. 2 to 4, a low-inductance current-sharing power module includes a ceramic substrate 3, an upper bridge chipset 4-1, a lower bridge chipset 4-2, a positive electrode 1-1, a positive electrode 1-2, and a negative electrode 2, a G electrode 6, an S electrode 7 and an output electrode 8.

An upper-layer copper sheet is arranged on the upper surface of the ceramic substrate 3, and the upper-layer copper sheet includes an upper-bridge copper-sheet area 3-1, a lower-bridge copper-sheet area 3-2, a negative-electrode copper-sheet area 3-3 and a signal copper-sheet area that are not connected to each other.

Specifically, the upper-bridge copper-sheet area 3-1 is arranged on the right half of the upper surface of the ceramic substrate 3 and is in a “concave” shape, and the lower-bridge copper-sheet area 3-2 is arranged on the left half of the upper surface of the ceramic substrate 3 and is in a “convex” shape. The main part of the upper-bridge copper-sheet area 3-1 and the main part of the lower-bridge copper-sheet area 3-2 are roughly in bilateral symmetry with respect to the center line of the upper surface of the ceramic substrate 3. The upper-bridge chipset 4-1 is evenly arranged on the upper surface of the upper-bridge copper-sheet area 3-1 to achieve the current sharing effect, and the upper-bridge chipset 4-1 is in connection with the lower-bridge copper-sheet area 3-1 through the upper-bridge link device 9. The positive electrode 1-1 and the positive electrode 1-2 are respectively arranged at two protruded ends of the “concave”-shaped upper-bridge copper-sheet area 3-1, and extend outward to facilitate to connect with the exterior. In one specific embodiment, as illustrated in FIG. 4, the upper-bridge chipset 4-1 includes eight upper-bridge chips, and the eight upper-bridge chips are evenly arranged on the upper-bridge copper-sheet area 3-1 in four rows and two columns. In another specific embodiment, as illustrated in FIG. 5, the upper-bridge link device 9 includes an upper-bridge link body and twelve link pins 9.1 to 9.12, one end of each of the twelve link pins 9.1 to 9.12 is in connection with the upper-bridge link body, and the other end of each of the eight link pins 9.5 to 9.12 is respectively coupled to the eight upper-bridge chips of the upper bridge chipset 4-1, and the other end of each of the remaining four link pins 9.1 to 9.4 is in connection with the lower-bridge copper-sheet area 3-2. The lower-bridge chipset 4-2 is evenly arranged on the upper surface of the lower-bridge copper-sheet area 3-2 to achieve the current sharing effect, and the lower-bridge chipset 4-2 is in connection with the negative-electrode copper-sheet area 3-3 through the lower-bridge link device 10. The output electrode 8 is coupled to the central protruded part of the “convex”-shaped lower-bridge copper-sheet area 3-2 and extend outward to facilitate to connect with the exterior. In one specific embodiment, as illustrated in FIG. 4, the lower-bridge chipset 4-2 includes eight lower-bridge chips, and the eight lower-bridge chips are evenly arranged on the upper surface of the lower-bridge copper-sheet area 3-2 in four rows and two columns. In another embodiment, as illustrated in FIG. 6, the lower-bridge link device 10 includes a lower bridge link body and ten link pins 10.1 to 10.10, one end of each of the ten link pins 10.1 to 10.10 is in connection with the lower-bridge link body, and the other end of each of the eight link pins 10.1 to 10.8 is respectively coupled to the eight low-bridge chips of the low-bridge chipset 4-2, the other end of the link pin 10.9 is coupled to the negative-electrode copper-sheet area 3-3, and the other end of the remaining link pin 10.10 is coupled to the signal copper-sheet area.

Specially, the negative-electrode copper-sheet area 3-3 is arranged at the intermediate part of the right edge of the upper surface of the ceramic substrate 3 and is semi-surrounded in the “concave”-shaped upper-bridge copper-sheet area 3-1, and the remaining parts of the negative-electrode copper-sheet area 3-3 are surrounded by the upper-bridge copper-sheet area 3-1 except one edge of the negative-electrode copper-sheet area 3-3. In one specific embodiment, the positive electrode 1-1 and the positive electrode 1-2 are respectively arranged at two protruded ends of the “convex”-shaped upper-bridge copper-sheet area 3-1, whereas the negative electrode 2 is arranged on the negative-electrode copper-sheet area 3-3, so that the positive electrode 1-1 and the positive electrode 1-2 are symmetrical with respect to the negative electrode 2.

Specifically, the signal copper area is arranged at both ends of the left edge of the upper surface of the ceramic substrate 3 and is located on both sides of the top part of the “convex”-shaped lower-bridge copper-sheet area 3-2. The signal copper area includes the paths respectively extending into the upper-bridge copper-sheet area 3-1 and the lower-bridge copper-sheet area 3-2. Specifically, the path extending into the upper-bridge copper-sheet area 3-1 and the path extending into the lower-bridge copper-sheet area 3-2 are in bilateral symmetry with respect to the center line of the upper surface of the ceramic substrate 3. In one specific embodiment, the G electrode 6 and the S electrode 7 are respectively in connection with different regions in the signal copper-sheet area and extend outward to facilitate to connect with other external structures. The S electrode 7 is coupled to the link pin 10.10 of the lower-bridge link device 10 through the signal copper-sheet area.

The upper bridge link device 9 and the lower bridge link device 10 are arranged in a laminated manner.

### Embodiment 3

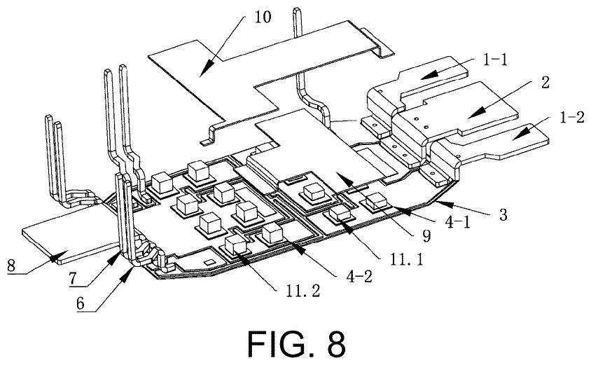

As illustrated in FIGS. 7 and 8, a low-inductance current-sharing power module includes a ceramic substrate 3, an upper-bridge chipset 4-1, a lower-bridge chipset 4-2, a positive electrode 1-1, a positive electrode 1-2, and an output electrode 8.

An upper-layer cooper sheet is arranged on the upper surface of the ceramic substrate 3, and the upper-layer copper sheet includes an upper-bridge copper-sheet area 3-1, a lower-bridge copper-sheet area 3-2, a negative electrode copper-sheet area 3-3 and a signal copper-sheet area that are not connected to each other.

Specifically, the upper-bridge copper-sheet area 3-1 is arranged on the right half of the upper surface of the ceramic substrate 3 and is in a “concave” shape, and the lower-bridge copper-sheet area 3-2 is arranged on the left half of the upper surface of the ceramic substrate 3 and is in a “convex” shape. The main part of the upper-bridge copper-sheet area 3-1 and the main part of the lower-bridge copper-sheet area 3-2 are roughly in bilateral symmetry with respect to the center line of the upper surface of the ceramic substrate 3. In one specific embodiment, the upper-bridge chipset 4-1 arranged on the upper-bridge copper-sheet area 3-1 and the lower-bridge chipset 4-2 arranged on the lower-bridge copper-sheet area 3-2 are in bilateral symmetry with respect to the center line of the upper surface of the ceramic substrate 3. The upper-bridge chipset 4-1 is in connection with the lower-bridge copper-sheet area 3-2 through the upper-bridge link device 9, and the lower-bridge chipset 4-2 is in connection with the negative copper-sheet area 3-3 through the lower-bridge link device 10. The upper-bridge link device 9 and the lower-bridge link device 10 are arranged in a laminated manner. Preferably, the upper-bridge chipset 4-1 includes eight upper-bridge chips, and the eight upper-bridge chips are evenly arranged on the upper surface of the upper-bridge copper-sheet area 3-1. The upper-bridge link device 9 is in connection with the upper bridge chipset 4-1 through the metal blocks 11. Specifically, as illustrated in FIG. 8, the upper-bridge link device 9 includes a first link body and eight upper-bridge metal blocks 11.1. The first link body is in connection with the eight chips of the upper-bridge chipset 4-1 through the eight upper-bridge metal blocks 11.1, respectively. Preferably, the lower-bridge chipset 4-2 includes eight lower-bridge chips, and the eight lower bridge chips are evenly arranged on the upper surface of the lower-bridge copper-sheet area 3-2. The lower-bridge link device 10 is in connection with the lower-bridge chipset 4-2 through the metal blocks 11. Specifically, as illustrated in FIG. 8, the lower-bridge link device 10 includes a second link body, a second link pin, a third link pin and eight lower-bridge metal blocks 11.2. The second link body is in connection with the eight chips of the lower-bridge chipset 4-2 through the eight lower-bridge metal blocks 11.2, respectively, and is coupled to the negative-electrode copper-sheet area 3-3 through the second link pin, and is coupled to the signal copper area through the third link pin. Preferably, the thickness of the lower-bridge metal block 11.2 is greater than the thickness of the upper-bridge metal block 11.1. The distance between the upper-bridge link device and the lower-bridge link device is adjusted through varying the thickness of the metal block, so that the upper-bridge link device 9 and the lower-bridge link device 10 are arranged in a laminated manner. In addition, the positive electrode 1-1 and the positive electrode 1-2 are installed at the two protruded ends of the upper surface of the “concave”-shaped upper-bridge copper-sheet area 3-1, and the output electrode 8 is installed on the central protruded part of the upper surface of the “convex”-shaped lower-bridge copper-sheet area 3-2.

Specifically, the negative-electrode copper-sheet area 3-3 is arranged at an intermediate part of the right edge of the upper surface of the ceramic substrate 3 and is semi-surrounded within the “concave”-shaped upper-bridge copper-sheet area 3-1. The remaining parts of the negative-electrode copper-sheet area 3-3 is surrounded by the upper-bridge copper-sheet area 3-1 except one edge of the negative-electrode copper-sheet area 3-3, and the negative electrode 2 is installed on the upper surface of the negative-electrode copper-sheet area 3-3. In one specific embodiment, the positive electrode 1-1 and the positive electrode 1-2 are respectively arranged at two protruded ends of the “concave”-shaped upper-bridge copper-sheet area 3-1, whereas the negative electrode 2 is arranged in the negative-electrode copper-sheet area 3-3, so that the positive electrode 1-1 and the positive electrode 1-2 are symmetrical with respect to the negative electrode 2.

Specifically, the signal copper-sheet area is arranged at both ends of the left edge of the upper surface of the ceramic substrate 3 and is located on both sides of the top part of the “convex”-shaped lower-bridge copper-sheet area 3-1, and includes the paths respectively extending into the upper-bridge copper-sheet area 3-1 and the lower-bridge copper-sheet area 3-2. Specifically, the path extending into the upper-bridge copper-sheet area 3-1 and the path extending into the lower-bridge copper-sheet area 3-2 are in bilateral symmetry with respect to the center line of the upper surface of the ceramic substrate 3.

The upper-bridge chipset 4-1 and the lower-bridge chipset 4-2 proposed by the present disclosure are evenly arranged on the upper surfaces of the upper-bridge copper-sheet area 3-1 and the lower-bridge copper-sheet area 3-2, respectively, and the upper-bridge copper-sheet area 3-1 and the lower-bridge copper-sheet area 3-2 are basically symmetrically arranged, which effectively implements the current sharing. The upper-bridge link device 9 and the lower-bridge link device 10 proposed by the present disclosure are placed in a laminated manner, which utilizes the effect of the cancellation between two magnetic fields to reduce the parasitic inductance of the power loop, thereby effectively reducing the loss of the power module and improving the usage frequency of the power module.

The descriptions and applications of the present disclosure herein are illustrative and are not intended to limit the scope of the present disclosure to the above-mentioned embodiments. The effects or advantages and other related descriptions mentioned in the description may not be reflected in the actual experimental examples due to the uncertainty of the specific condition parameters or other factors, the effects or advantages and other related descriptions are not used to limit the scope of the present disclosure. The deformations and the variations of the embodiments disclosed herein are possible, and the substitutions and the equivalents of the various components of the embodiments is well known to those of ordinary skill in the art. It will be apparent to those skilled in the art that the present disclosure may be implemented in other forms, structures, arrangements, proportions, and with other components, materials and parts without departing from the spirit or essential characteristics of the present disclosure. Other modifications and variations may be made to the embodiments disclosed herein without departing from the scope and spirit of the present disclosure.

What is claimed is:

1. A low-inductance current-sharing power module, comprising a ceramic substrate, a first chipset, a second chipset, positive electrodes, a negative electrode and an output electrode, wherein
an upper-layer copper sheet is arranged on an upper surface of the ceramic substrate, and the upper-layer copper sheet includes a first copper-sheet area, a second copper-sheet area, a negative-electrode copper-sheet area and a signal copper-sheet area that are not connected to each other;
the first chipset is evenly arranged on an upper surface of the first copper-sheet area and is coupled to the second copper-sheet area through a first link device;
the second chipset is evenly arranged on an upper surface of the second copper-sheet area and is coupled to the negative-electrode copper-sheet area and the signal copper-sheet area through a second link device, and the second link device and the first link device are arranged in a laminated manner; and
the positive electrode is coupled to the first copper-sheet area and extends outward, the negative electrode is coupled to the negative-electrode copper-sheet area and extends outward, and the output electrode is coupled to the second copper-sheet area and extends outward.

2. The low-inductance current sharing power module according to claim 1, wherein the first copper-sheet area is arranged on a right half of the upper surface of the ceramic substrate and is in a “concave” shape, and the second copper-sheet area is arranged on a left half of the upper surface of the ceramic substrate and is in a “convex” shape, the negative-electrode copper-sheet area is arranged at an intermediate part of a right edge of the upper surface of the ceramic substrate and is semi-surrounded within the “concave”-shaped first copper-sheet area, the signal copper-sheet area is arranged at both ends of a left edge of the upper surface of the ceramic substrate and is located at both sides of a top part of the “convex”-shaped second copper-sheet area, and the signal copper-sheet area includes paths respectively extending into the first copper-sheet area and the second copper-sheet area, and the path extending into the first copper-sheet area and the path extending into the second copper-sheet area are in bilateral symmetry with respect to a center line of the upper surface of the ceramic substrate.

3. The low-inductance current-sharing power module according to claim 1, wherein the first chipset arranged on the first copper-sheet area and the second chipset arranged on the second copper-sheet area are in bilateral symmetry with respect to the center line of the ceramic substrate.

4. The low-inductance current-sharing power module according to claim 1, wherein two positive electrodes are respectively arranged on both protruded ends of the “concave”-shaped first copper-sheet area, and the negative electrode is arranged on the negative-electrode copper-sheet area, the two positive electrodes are symmetrical with respect to the negative electrode, and the output electrode is arranged on a central protruded part of the “convex”-shaped second copper-sheet area.

5. The low-inductance current-sharing power module according to claim 1, wherein the first link device and the second link device are respectively coupled to the first chipset and the second chipset through metal blocks.

6. The low-inductance current-sharing power module according to claim 1, wherein the first link device includes a first link body, a first link pin and first metal blocks of a number of p, and the first link body is respectively coupled to p chips of the first chipset through the p first metal blocks, where p denotes a positive integer, the first link body is coupled to the second copper-sheet area through the first link pin.

7. The low-inductance current-sharing power module according to claim 1, wherein the second link device includes a second link body, a second link pin, a third link pin and second metal blocks of a number of q, the second link body is respectively coupled to q chips of the second chipset through q second metal blocks, and a thickness of the second metal block is greater than a thickness of the first metal block, where q denotes a positive integer, the second link body is coupled to the negative-electrode copper-sheet area through the second link pin, and the second link body is coupled to the signal copper-sheet area through the third link pin.

8. The low-inductance current-sharing power module according to claim 1, wherein the first link device includes a first link body and a plurality of link pins, and a first end of each of the link pins is in connection with the first link body, a second end of each of p link pins is respectively coupled to p chips of the first chipset, and a second end of each of remaining link pins is coupled to the second copper-sheet area, where p denotes a positive integer.

9. The low-inductance current-sharing power module according to claim 1, wherein the second link device includes a second link body and a plurality of link pins, a first end of each of the link pins is in connection with the second link body, a second end of each of q link pins is respectively coupled to q chips of the second chipset, and a second end of each of r link pins is coupled to the negative-electrode copper-sheet area, and a second end of each of the remaining link pins is coupled to the signal copper-sheet area, where q and r denote positive integers.

10. The low-inductance current-sharing power module according to claim 1, wherein further comprising a G electrode and an S electrode, the G electrode and the S electrode are respectively in connection with different regions in the signal copper-sheet area and extend outward, wherein the S electrode is in connection with the second link device through the signal copper-sheet area.
